(19) United States
(12) Patent Application Publication
(10) Pub. No.: US 2007/0202693 A1
(43) Pub. Date: Aug. 30, 2007

(54) Method of and Apparatus for Forming Three-Dimensional Structures Integral With Semiconductor Based Circuitry

(76) Inventors: Adam L. Cohen, Los Angeles, CA (US); Gang Zhang, Monterey Park, CA (US)

Correspondence Address: MICROFABRICA INC.;ATT: DENNIS R. SMALLEY, 7911 HASKELL AVENUE, VAN NUYS, CA, 91406, US

(21) Appl. No.: 11/668,299

(22) Filed: Jan. 29, 2007

Related U.S. Application Data
(63) Continuation of application No. 10/434,295, filed on May 7, 2003, now abandoned.
(60) Provisional application No. 60/379,133, filed on May 7, 2002.

(51) Int. Cl. H01L 21/44; C23C 28/00

(52) U.S. Cl. 438/652; 205/183

(57) ABSTRACT

Enhanced Electrochemical fabrication processes are provided that can form three-dimensional multi-layer structures using semiconductor based circuitry as a substrate. Electrically functional portions of the structure are formed from structural material (e.g. nickel) that adheres to contact pads of the circuit. Aluminum contact pads and silicon structures are protected from copper diffusion damage by application of appropriate barrier layers. In some embodiments, nickel is applied to the aluminum contact pads via solder bump formation techniques using electroless nickel plating. In other embodiments, selective electroless copper plating or direct metallization is used to plate sacrificial material directly onto dielectric passivation layers. In still other embodiments, structural material deposition locations are shielded, then sacrificial material is deposited, the shielding is removed, and then structural material is deposited. In still other embodiments structural material is made to attach to non-contact pad regions.

### RELATED APPLICATIONS

This application is a continuation of U.S. Provisional patent application Ser. No. 10/434,295 filed on May 7, 2003 which claims benefit of U.S. Provisional Patent Application No. 60/379,133, filed on May 7, 2002. These applications are hereby incorporated herein by reference as if set forth in full.

### FIELD OF THE INVENTION

This invention relates to the field of electrochemical deposition and more particularly to the field of electrochemical fabrication which involving electrochemical deposition of one or more materials according to desired cross-sectional configurations so as to build up three-dimensional structures from a plurality of at least partially adhered layers of deposited material. More particularly the invention relates to the integration of multilayer electrochemically fabricated structures with semiconductor circuitry and in particular to the formation of such multilayer structures on integrated circuits.

### BACKGROUND

A technique for forming three-dimensional structures (e.g. parts, components, devices, and the like) from a plurality of adhered layers was invented by Adam L. Cohen and is known as Electrochemical Fabrication. It is being commercially pursued by Microfabrica Inc. (formerly MEMGen® Corporation) of Burbank, Calif. under the name EFAB™. This technique was described in U.S. Pat. No. 6,027,630, issued on Feb. 22, 2000. This electrochemical deposition technique allows the selective deposition of a material using a unique masking technique that involves the use of a mask that includes patterned conformable material on a support structure that is independent of the substrate onto which plating will occur. When desiring to perform an electrodeposition using the mask, the conformable portion of the mask is brought into contact with a substrate while in the presence of a plating solution such that the contact of the conformable portion of the mask to the substrate inhibits deposition at selected locations. For convenience, these masks might be generically called conformable contact masks; the masking technique may be generically called a conformable contact mask plating process. More specifically, in the terminology of Microfabrica Inc. such masks have come to be known as INSTANT MASKS™ and the process known as INSTANT MASKING™ or INSTANT MASK™ plating. Selective depositions using conformable contact mask plating may be used to form single layers of material or may be used to form multi-layer structures. The teachings of the '630 patent are hereby incorporated herein by reference as if set forth in full herein. Since the filing of the patent application that led to the above noted patent, various papers about conformable contact mask plating (i.e. INSTANT MASKING) and electrochemical fabrication have been published:
1. A. Cohen, G. Zhang, F. Tseng, F. Mansfeld, U. Frodis and P. Will, “EFAB: Batch production of functional, fully-dense metal parts with micro-scale features”, Proc. 9th Solid Freeform Fabrication, The University of Texas at Austin, p 161, Aug. 1998.
2. A. Cohen, G. Zhang, F. Tseng, F. Mansfeld, U. Frodis and P. Will, “EFAB: Rapid, Low-Cost Desktop Micromachining of High Aspect Ratio True 3-D MEMS”, Proc. 12th IEEE Micro Electro Mechanical Systems Workshop, IEEE, p 244, January 1999.
3. A. Cohen, “3-D Micromachining by Electrochemical Fabrication”, Micromachine Devices, March 1999.
4. G. Zhang, A. Cohen, U. Frodis, F. Tseng, F. Mansfeld, and P. Will, “EFAB: Rapid Desktop Manufacturing of True 3-D Microstructures”, Proc. 2nd International Conference on Integrated MicroNanotechnology for Space Applications, The Aerospace Co., Apr. 1999.
5. F. Tseng, U. Frodis, G. Zhang, A. Cohen, F. Mansfeld, and P. Will, “EFAB: High Aspect Ratio, Arbitrary 3-D Metal Microstructures using a Low-Cost Automated Batch Process”, 3rd International Workshop on High Aspect Ratio MicroStructure Technology (HARMST'99), June 1999.
6. A. Cohen, U. Frodis, F. Tseng, G. Zhang, F. Mansfeld, and P. Will, “EFAB: Low-Cost, Automated Electrochemical Batch Fabrication of Arbitrary 3-D Microstructures”, Micromachining and Microfabrication Process Technology, SPIE 1999 Symposium on Micromachining and Microfabrication, September 1999.
7. F. Tseng, G. Zhang, U. Frodis, A. Cohen, F. Mansfeld, and P. Will, “EFAB: High Aspect Ratio, Arbitrary 3-D Metal Microstructures using a Low-Cost Automated Batch Process”, MEMS Symposium, ASME 1999 International Mechanical Engineering Congress and Exposition, November, 1999.
8. A. Cohen, “Electrochemical Fabrication (EFAB™)”, Chapter 19 of The MEMS Handbook, edited by Mohamed Gad-EI-Hak, CRC Press, 2002.
9. “Microfabrication—Rapid Prototyping's Killer Application”, pages 1-5 of the Rapid Prototyping Report, CAD/CAM Publishing, Inc., June 1999.

The disclosures of these nine publications are hereby incorporated herein by reference as if set forth in full herein.

The electrochemical deposition process may be carried out in a number of different ways as set forth in the above patent and publications. In one form, this process involves the execution of three separate operations during the formation of each layer of the structure that is to be formed:
1. Selectively depositing at least one material by electrodeposition upon one or more desired regions of a substrate.
2. Then, blanket depositing at least one additional material by electrodeposition so that the additional deposit covers both the regions that were previously selectively deposited onto, and the regions of the substrate that did not receive any previously applied selective depositions.
3. Finally, planarizing the materials deposited during the first and second operations to produce a smoothed surface of a first layer of desired thickness having at least one region containing the at least one material and at least one region containing at least the one additional material.

After formation of the first layer, one or more additional layers may be formed adjacent to the immediately preceding layer and adhered to the smoothed surface of that preceding layer. These additional layers are formed by repeating the first through third operations one or more times wherein the formation of each subsequent layer treats the previously formed layers and the initial substrate as a new and thickening substrate.

Once the formation of all layers has been completed, at least a portion of at least one of the materials deposited is generally removed by an etching process to expose or release the three-dimensional structure that was intended to be formed.

The preferred method of performing the selective electrodeposition involved in the first operation is by conformable contact mask plating. In this type of plating, one or more conformable contact (CC) masks are first formed. The CC masks include a support structure onto which a patterned conformable dielectric material is adhered or formed. The conformable material for each mask is shaped in accordance with a particular cross-section of material to be plated. At least one CC mask is needed for each unique cross-sectional pattern that is to be plated.

The support for a CC mask is typically a plate-like structure formed of a metal that is to be selectively electroplated and from which material to be plated will be dissolved. In this typical approach, the support will act as an anode in an electroplating process. In an alternative approach, the support may instead be a porous or otherwise perforated material through which deposition material will pass during an electroplating operation on its way from a distal anode to a deposition surface. In either approach, it is possible for CC masks to share a common support, i.e. the patterns of conformable dielectric material for plating multiple layers of material may be located in different areas of a single support structure. When a single support structure contains multiple plating patterns, the entire structure is referred to as the CC mask while the individual plating masks may be referred to as “submasks”. In the present application such a distinction will be made only when relevant to a specific point being made.

In preparation for performing the selective deposition of the first operation, the conformable portion of the CC mask is placed in registration with and pressed against a selected portion of the substrate (or onto a previously formed layer or onto a previously deposited portion of a layer) on which deposition is to occur. The pressing together of the CC mask and substrate occur in such a way that all openings, in the conformable portions of the CC mask contain plating solution. The conformable material of the CC mask that contacts the substrate acts as a barrier to electrodeposition while the openings in the CC mask that are filled with electroplating solution act as pathways for transferring material from an anode (e.g. the CC mask support) to the non-contacted portions of the substrate (which act as a cathode during the plating operation) when an appropriate potential and/or current are supplied.

An example of a CC mask and CC mask plating are shown in FIGS. 1A-1C. FIG. 1A shows a side view of a CC mask 8 consisting of a conformable or deformable (e.g. elastomeric) insulator 10 patterned on an anode 12. The anode has two functions. One is as a supporting material for the patterned insulator 10 to maintain its integrity and alignment since the pattern may be topologically complex (e.g., involving isolated “islands” of insulator material). The other function is as an anode for the electroplating operation. FIG. 1A also depicts a substrate 6 separated from mask 8. CC mask plating selectively deposits material 22 onto a substrate 6 by simply pressing the insulator against the substrate then electrodepositing material through apertures 26a and 26b in the insulator as shown in FIG. 1B. After deposition, the CC mask is separated, preferably non-destructively, from the substrate 6 as shown in FIG. 1C. The CC mask plating process is distinct from a “through-mask” plating process in that in a through-mask plating process the separation of the masking material from the substrate would occur destructively. As with through-mask plating, CC mask plating deposits material selectively and simultaneously over the entire layer. The plated region may consist of one or more isolated plating regions where these isolated plating regions may belong to a single structure that is being formed or may belong to multiple structures that are being formed simultaneously. In CC mask plating, as individual masks are not intentionally destroyed in the removal process, they may be usable in multiple plating operations.

Another example of a CC mask and CC mask plating is shown in FIGS. 1D-1G. FIG. 1D shows an anode 12′ separated from a mask 8′ that comprises a patterned conformable material 10′ and a support structure 20. FIG. 1D also depicts substrate 6 separated from the mask 8′. FIG. 1E illustrates the mask 8′ being brought into contact with the substrate 6. FIG. 1F illustrates the deposit 22′ that results from conducting a current from the anode 12′ to the substrate 6. FIG. 1G illustrates the deposit 22′ on substrate 6 after separation from mask 8′. In this example, an appropriate electrolyte is located between the substrate 6 and the anode 12′ and a current of ions coming from one or both of the solution and the anode are conducted through the opening in the mask to the substrate where material is deposited. This type of mask may be referred to as an anodeless INSTANT MASK™ (AIM) or as an anodeless conformable contact (ACC) mask.

Unlike through-mask plating, CC mask plating allows CC masks to be formed completely separate from the fabrication of the substrate on which plating is to occur (e.g. separate from a three-dimensional (3D) structure that is being formed). CC masks may be formed in a variety of ways, for example, a photolithographic process may be used. All masks can be generated simultaneously prior to structure fabrication rather than during it. This separation makes possible a simple, low-cost, automated, self-contained, and internally-clean “desktop factory” that can be installed almost anywhere to fabricate 3D structures, leaving any required clean room processes, such as photolithography to be performed by service bureaus or the like.

An example of the electrochemical fabrication process discussed above is illustrated in FIGS. 2A-2F. These figures show that the process involves deposition of a first material 2 which is a sacrificial material and a second material 4 which is a structural material. The CC mask 8, in this example, includes a patterned conformable material (e.g. an elastomeric dielectric material) 10 and a support 12 which is made from deposition material 2. The conformal portion of the CC mask is pressed against substrate 6 with a plating solution 14 located within the openings 16 in the conformable material 10. An electric current, from power supply 18, is then passed through the plating solution 14 via (a) support 12 which doubles as an anode and (b) substrate 6 which doubles as a cathode. FIG. 2A, illustrates that the passing of current causes material 2 within the plating solution and material 2 from the anode 12 to be selectively transferred to and plated on the substrate 6. After electroplating the first deposition material 2 onto the substrate 6 using CC mask 8, the CC mask 8 is removed as shown in FIG. 2B. FIG. 2C depicts the second deposition material 4 as having been blanket-deposited (i.e. non-selectively deposited) over the previously deposited first deposition material 2 as well as over the other portions of the substrate 6. The blanket deposition occurs by electroplating from an anode (not shown), composed of the second material, through an appropriate plating solution (not shown), and to the cathode/substrate 6. The entire two-material layer is then planarized to achieve precise thickness and flatness as shown in FIG. 2D. After repetition of this process for all layers, the multi-layer structure 20 formed of the second material 4 (i.e. structural material) is embedded in first material 2 (i.e. sacrificial material) as shown in FIG. 2E. The embedded structure is etched to yield the desired device, i.e. structure 20, as shown in FIG. 2F.

Various components of an exemplary manual electrochemical fabrication system 32 are shown in FIGS. 3A-3C. The system 32 consists of several subsystems 34, 36, 38, and 40. The substrate holding subsystem 34 is depicted in the upper portions of each of FIGS. 3A to 3C and includes several components: (1) a carrier 48, (2) a metal substrate 6 onto which the layers are deposited, and (3) a linear slide 42 capable of moving the substrate 6 up and down relative to the carrier 48 in response to drive force from actuator 44. Subsystem 34 also includes an indicator 46 for measuring differences in vertical position of the substrate which may be used in setting or determining layer thicknesses and/or deposition thicknesses. The subsystem 34 further includes feet 68 for carrier 48 which can be precisely mounted on subsystem 36.

The CC mask subsystem 36 shown in the lower portion of FIG. 3A includes several components: (1) a CC mask 8 that is actually made up of a number of CC masks (i.e. submasks) that share a common support/anode 12, (2) precision X-stage 54, (3) precision Y-stage 56, (4) frame 72 on which the feet 68 of subsystem 34 can mount, and (5) a tank 58 for containing the electrolyte 16. Subsystems 34 and 36 also include appropriate electrical connections (not shown) for connecting to an appropriate power source (not shown) for driving the CC masking process.

The blanket deposition subsystem 38 is shown in the lower portion of FIG. 3B and includes several components: (1) an anode 62, (2) an electrolyte tank 64 for holding plating solution 66, and (3) frame 74 on which feet 68 of subsystem 34 may sit. Subsystem 38 also includes appropriate electrical connections (not shown) for connecting the anode to an appropriate power supply (not shown) for driving the blanket deposition process.

The planarization subsystem 40 is shown in the lower portion of FIG. 3C and includes a lapping plate 52 and associated motion and control systems (not shown) for planarizing the depositions.

In addition to the above teachings, the '630 patent sets forth a process for integrating EFAB production with integrated circuits. In this process the structural EFAB material is plated onto and in electrical contact with aluminum contact pads on the integrated circuit. These contact pads may be considered primary contact pads and the locations to which contact with the EFAB structural material will be made. In the described process the integrated circuit design is modified to include secondary contact pads (i.e. one or more pads) that are electrically connected to the primary pads but are spaced therefrom by a distance. The secondary contact pads provide connection points for feeding current to the primary contact pads so that the primary pads may function as cathodes during electroplating operations. The process is illustrated in FIGS. 13A-13I of that patent and is outlined as follows:

1. The Process Starts with
a. An integrated circuit that includes a silicon wafer 38, a primary contact pad 40, and a secondary contact pad 41 connected to the primary pad by conductor 42. With the exception of the contact pads 40 and 41 the integrated circuit is covered by passivation layer 44 (FIGS. 13A & 13B); and
b. A polyimide 34 coated copper disk 36. The polyimide may be coated onto the disk by spin coating.

2. The copper disk 36 is adhered to the bottom surface of the silicon wafer 38 with the polyimide 34 coated surface of the copper disk located between the copper and the silicon.

3. The silicon wafer is partially sawed through which assists in separation of the die after processing.

4. A photosensitive polyimide 35 is spin coated onto the top surface of wafer 38. This coating provides an additional passivation layer and potentially protects aluminum pads 40 and 41 during subsequent etching operations and it fills saw line 46.

5. The polyimide 35 is patterned by selective exposure to light and subsequent development to expose contact pads 40 and 41.

6. The wafer is degreased and immersed in zincate plating solution which provides a thin coating over the exposed aluminum contact pads to increase adhesion of subsequently deposited material.

7. A photoresist is applied and patterned leaving a valley into which copper may be deposited to form a bus 48 that connects contact pads 41 (FIG. 13D). Copper is deposited, for example by sputtering and the photoresist is removed leaving behind copper bus 48.

8. A photoresist is applied and patterned to cover most of bus 48 to prevent nickel from depositing thereon.

9. Electrical contact is made with the portion of the bus 48 that is not covered by photoresist and then plating enough nickel 50 (FIG. 13E) on aluminum pad 40 to allow subsequent planarization

10. The photoresist is removed thereby exposing the entire copper bus 48.

11. A thin plating base of copper 51 is deposited, e.g. by sputtering, over the entire surface of the integrated circuit.

12. Electrical contact is made with the copper and a sufficient amount of copper 52 is then electroplated over the entire wafer surface to allow planarization (FIG. 13F).

13. The surface is planarized to expose the nickel 50 (FIG. 13G).

14. Layers of the microstructure are electroplated (FIG. 13H).

15. The copper deposited by electroplating and sputtering is removed by etching.

16. The polyimide 35 is stripped thereby exposing the resulting microstructure device 54 attached to wafer 38 (FIG. 13I).

Another method for forming microstructures from electroplated metals (i.e. using electrochemical fabrication techniques) is taught in U.S. Pat. No. 5,190,637 to Henry Guckel, entitled “Formation of Microstructures by Multiple Level Deep X-ray Lithography with Sacrificial Metal Layers”. This patent teaches the formation of metal structure utilizing mask exposures. A first layer of a primary metal is electroplated onto an exposed plating base to fill a void in a photoresist, the photoresist is then removed and a secondary metal is electroplated over the first layer and over the plating base. The exposed surface of the secondary metal is then machined down to a height which exposes the first metal to produce a flat uniform surface extending across both the primary and secondary metals. Formation of a second layer may then begin by applying a photoresist layer over the first layer and then repeating the process used to produce the first layer. The process is then repeated until the entire structure is formed and the secondary metal is removed by etching. The photoresist is formed over the plating base or previous layer by casting and the voids in the photoresist are formed by exposure of the photoresist through a patterned mask via X-rays or UV radiation.

Even in view of these teachings a need remains in the electrochemical fabrication arts for alternative processes and simpler processes for integrating electrochemically fabricated structures with integrated circuits and particularly for processes that allow formation of multilayer electrochemically fabricated structures on and in electrical contact with semiconductor produced circuitry.

### SUMMARY OF THE INVENTION

It is an object of some embodiments of various aspects of the present invention to provide alternative processes for integrating electrochemically fabricated multilayer structures with integrated circuits.

It is an object of some embodiments of various aspects of the present invention to provide simpler processes for integrating electrochemically fabricated multilayer structures with integrated circuits.

It is an object of some embodiments of various aspects of the present invention to provide simpler processes that allow formation of multilayer electrochemically fabricated structures on and in electrical contact with semiconductor produced circuitry.

Other objects and advantages of various aspects of the invention will be apparent to those of skill in the art upon review of the teachings herein. The various aspects of the invention, set forth explicitly herein or otherwise ascertained from the teachings herein, may address any one of the above objects alone or in combination, or alternatively may not address any of the objects set forth above but instead address some other object ascertained from the teachings herein. It is not intended that all of these objects be addressed by any single aspect of the invention even though that may be the case with regard to some aspects.

A first aspect of the invention provides an electrochemical fabrication process for producing a three-dimensional structure from a plurality of adhered layers, the process including: (A) selectively depositing at least a portion of a layer onto the substrate, wherein the substrate may include previously deposited material; (B) forming a plurality of layers such that successive layers are formed adjacent to and adhered to previously deposited layers, wherein said forming includes repeating operation (A) a plurality of times; wherein at least a plurality of the selective depositing operations include: (1) locating a selected mask on a substrate; (2) in presence of a plating solution, conducting an electric current between an anode and the substrate through at least one opening in the selected mask, such that a selected deposition material is deposited onto the substrate to form at least a portion of a layer; and (3) separating the selected mask from the substrate; wherein the substrate includes a semiconductor wafer or single die containing electrical circuitry and having contact pads to which structural material is to connect; and wherein the process of contacting the contact pads with structural material includes treating the wafer or die with a transition treatment and then applying a structural material to the contact pads by application of an electroless plating solution to the contact pads for a sufficient time to form a deposition of desired thickness.

A second aspect of the invention provides an electrochemical fabrication process for producing a three-dimensional structure from a plurality of adhered layers, the process including: (A) selectively depositing at least a portion of a layer onto the substrate, wherein the substrate may include previously deposited material; (B) forming a plurality of layers such that successive layers are formed adjacent to and adhered to previously deposited layers, wherein said forming includes repeating operation (A) a plurality of times; wherein at least a plurality of the selective depositing operations include: (1) locating a selected mask on a substrate; (2) in presence of a plating solution, conducting an electric current between an anode and the substrate through at least one opening in the selected mask, such that a selected deposition material is deposited onto the substrate to form at least a portion of a layer; and (3) separating the selected mask from the substrate; wherein the substrate includes a semiconductor wafer or single die containing electrical circuitry and having contact pads to which structural material is to connect; and wherein the process of forming a conductive layer over a surface of the wafer or die includes: (a) shielding at least the contact pads with a shielding material; (b) depositing a sacrificial material to unshielded regions using at least one of direct metallization or direct plating or electroless deposition; (c) removing the shielding after a deposition of the sacrificial material; and (d) depositing a structural material to the contact pads.

A third aspect of the invention provides an electrochemical fabrication process for producing a three-dimensional structure from a plurality of adhered layers, the process including: selectively depositing at least a portion of a layer onto the substrate, wherein the substrate may include previously deposited material; (A) forming a plurality of layers such that successive layers are formed adjacent to and adhered to previously deposited layers, wherein said forming includes repeating operation (A) a plurality of times; wherein at least a plurality of the selective depositing operations include: (1) locating a selected mask on a substrate; (2) in presence of a plating solution, conducting an electric current between an anode and the substrate through at least one opening in the selected mask, such that a selected deposition material is deposited onto the substrate to form at least a portion of a layer; and (3) separating the selected mask from the substrate; wherein the substrate includes a semiconductor wafer or single die containing electrical circuitry and having contact pads to which structural material is to connect and having regions of dielectric where structural material is to adhere; and wherein the process of contacting the structural material to regions of dielectric material includes depositing a conductive base material, in a patterned or unpatterned formation, depositing structural material to at least selected locations of the base material and, if base material exists in any regions which are not overlaid by structural material, subsequently removing any such base material that is not overlaid.

Further aspects of the invention will be understood by those of skill in the art upon reviewing the teachings herein. Other aspects of the invention may involve apparatus that can be used in implementing one or more of the above method aspects of the invention. These other aspects of the invention may provide various combinations of the aspects presented above, and/or additions of various features of one or more embodiments to the aspects presented above as well as provide other configurations, structures, functional relationships, and processes that have not been specifically set forth above.

### BRIEF DESCRIPTION OF THE DRAWINGS

FIGS. 1A-1C schematically depict side views of various stages of a CC mask plating process, while FIGS. 1D-G schematically depict side views of various stages of a CC mask plating process using a different type of CC mask.

FIGS. 2A-2F schematically depict side views of various stages of an electrochemical fabrication process as applied to the formation of a particular structure where a sacrificial material is selectively deposited while a structural material is blanket deposited.

FIGS. 3A-3C schematically depict side views of various example subassemblies that may be used in manually implementing the electrochemical fabrication method depicted in FIGS. 2A-2F.

FIGS. 4A-4F schematically depict the formation of a first layer of a structure using adhered mask plating where the blanket deposition of a second material overlays both the openings between deposition locations of a first material and the first material itself.

FIG. 4G depicts the completion of formation of the first layer resulting from planarizing the deposited materials to a desired level.

FIGS. 4H and 4I respectively depict the state of the process after formation of the multiple layers of the structure and after release of the structure from the sacrificial material.

FIGS. 5A-5L schematically depict side views of various stages of a process according to a first embodiment for forming electrochemically fabricated structures on integrated circuits.

FIGS. 5A-5L schematically depict side views of various stages of a process according to a first embodiment for forming electrochemically fabricated structures on integrated circuits.

FIGS. 6A-6F schematically depict side views of various stages of a process according to one variation of a second embodiment for forming electrochemically fabricated structures on integrated circuits.

FIGS. 7A-7H schematically depict side views of various stages of a process according to another variation of a second embodiment for forming electrochemically fabricated structures on integrated circuits.

FIGS. 8A-8H schematically depict side views of various stages of a process according to another variation of a second embodiment for forming electrochemically fabricated structures on integrated circuits.

FIGS. 9A-9I schematically depict side views of various stages of a process according to a third embodiment for forming electrochemically fabricated structures on integrated circuits.

FIGS. 10A-10I schematically depict side views of various stages of a process according to a fourth embodiment for forming electrochemically fabricated structures on integrated circuits.

FIG. 11A-11K schematically depict side views of various stages of a process according to a fifth embodiment for forming electrochemically fabricated structures on integrated circuits.

### DETAILED DESCRIPTION OF PREFERRED EMBODIMENTS OF THE INVENTION

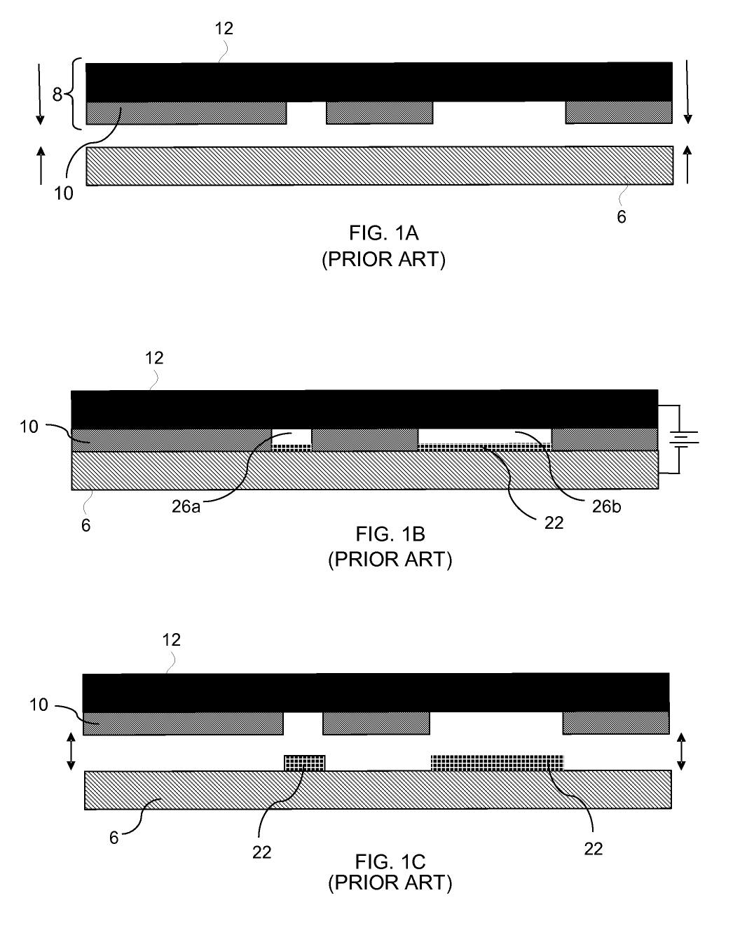

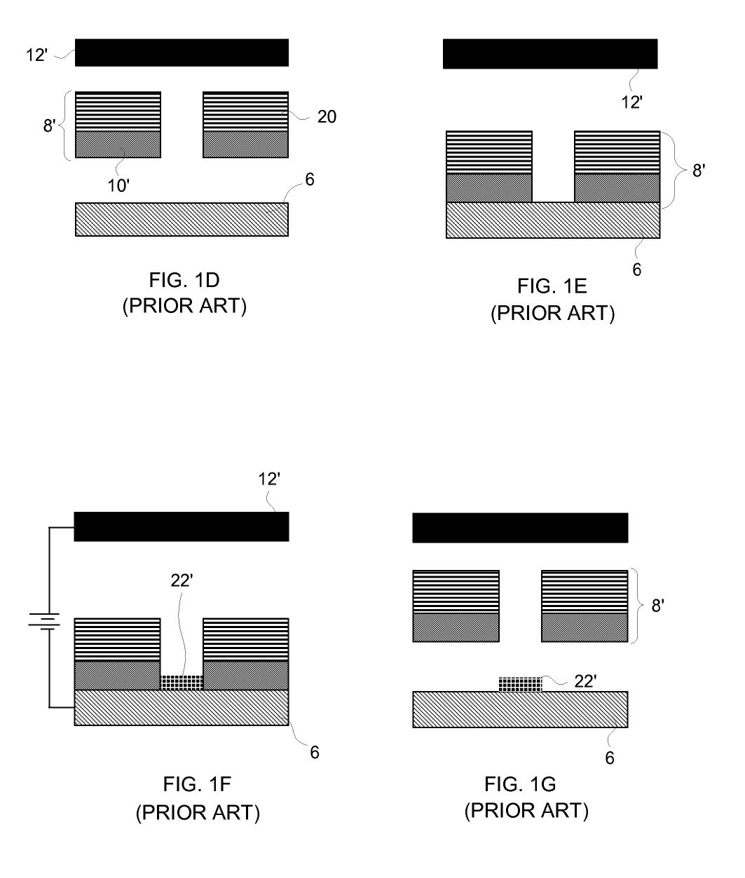

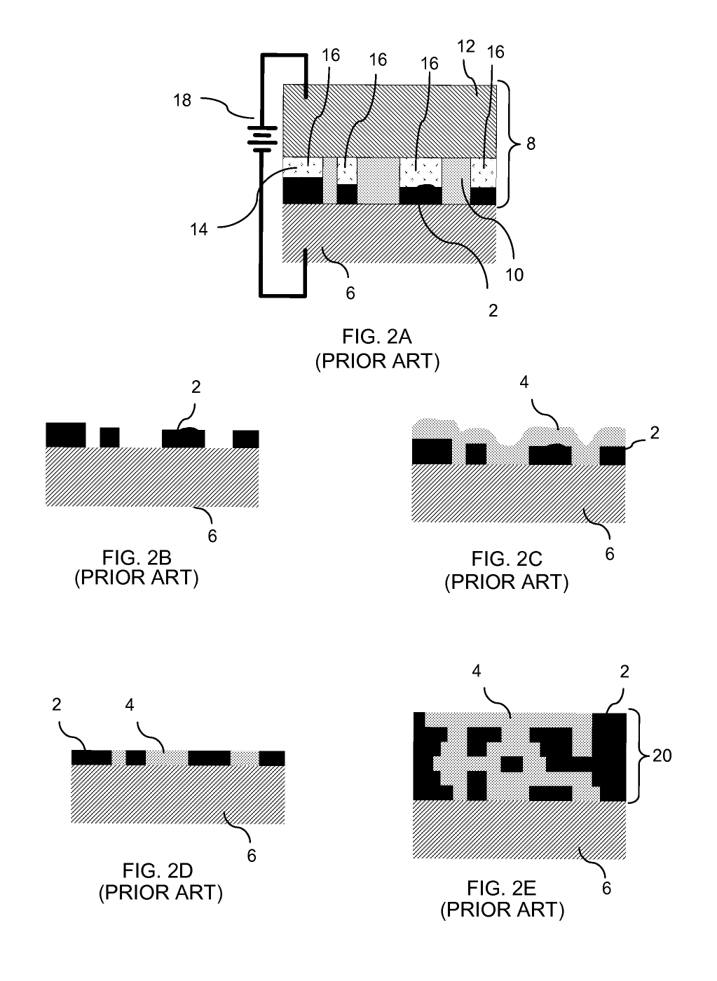

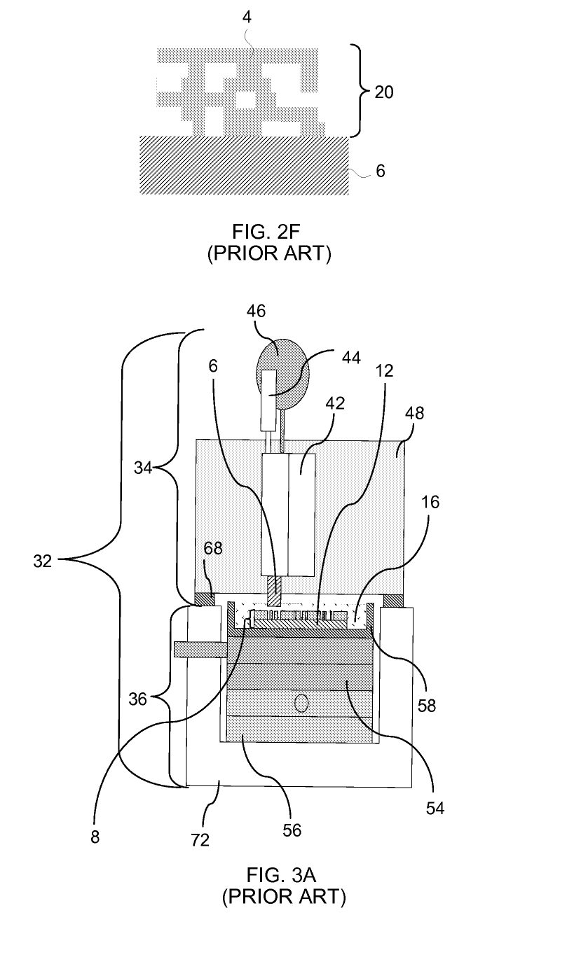

FIGS. 1A-1G, 2A-2F, and 3A-3C illustrate various features of one form of electrochemical fabrication that are known. Other electrochemical fabrication techniques are set forth in the '630 patent referenced above, in the various previously incorporated publications, in various other patents and patent applications incorporated herein by reference, still others may be derived from combinations of various approaches described in these publications, patents, and applications, or are otherwise known or ascertainable by those of skill in the art from the teachings set forth herein. All of these techniques may be combined with those of the various embodiments of various aspects of the invention to yield enhanced embodiments. Still other embodiments may be derived from combinations of the various embodiments explicitly set forth herein.

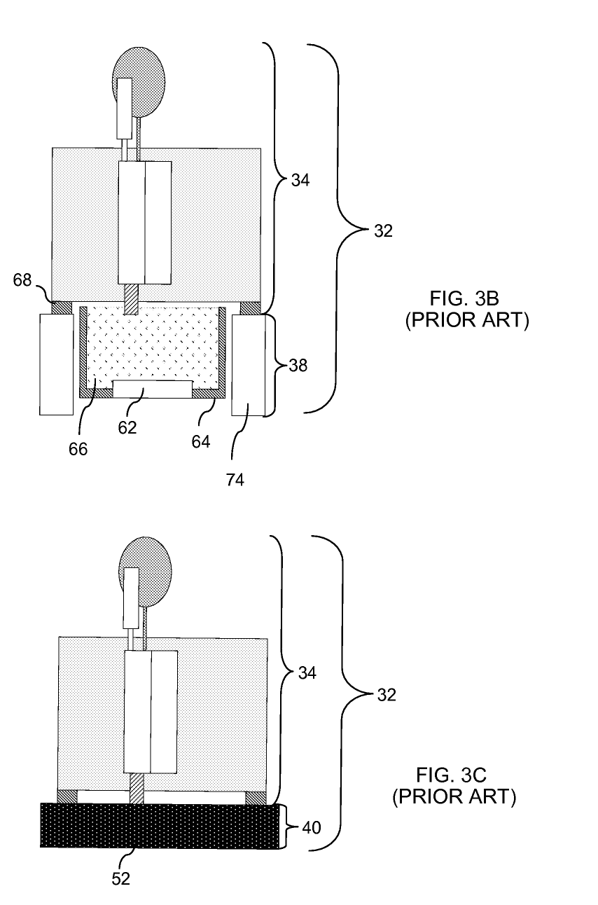

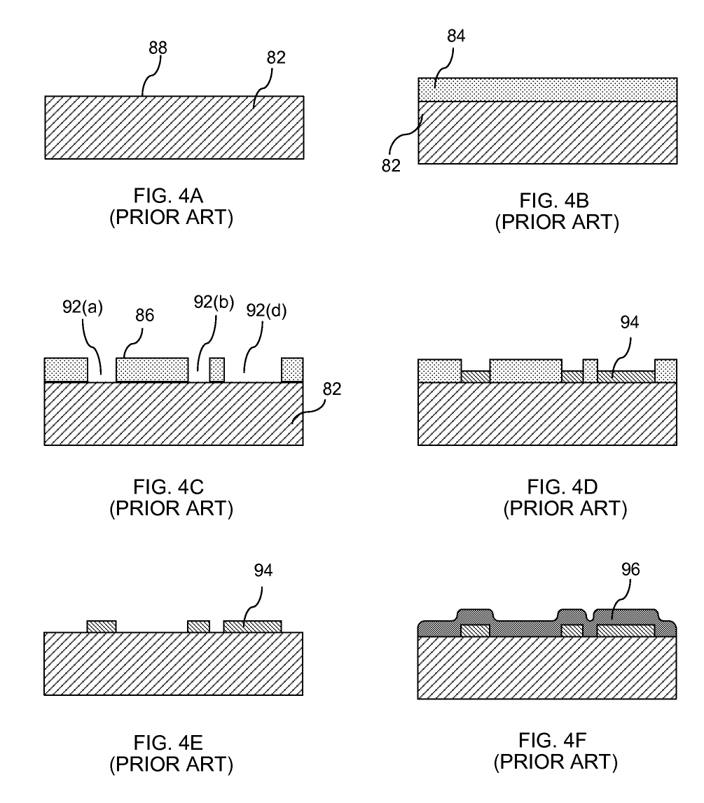

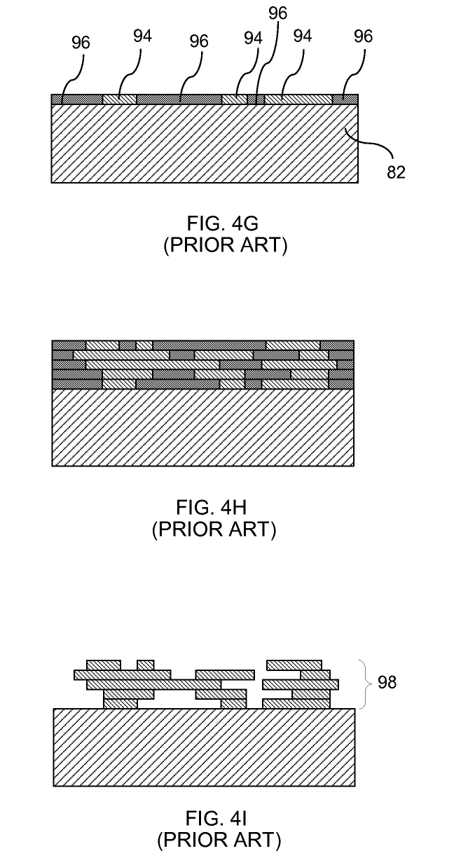

FIGS. 4A-4F illustrate various stages in the formation of a single layer of a multi-layer fabrication process where a second metal is deposited on a first metal as well as in openings in the first metal so that the first and second metal form part of the layer. In FIG. 4A a side view of a substrate 82 is shown onto which patternable photoresist 84 is cast as shown in FIG. 4B. In FIG. 4C a pattern of resist is shown that results from the curing, exposing, and developing of the resist. The patterning of the photoresist 84 results in openings or apertures 92(a)-92(c) extending from a surface 86 of the photoresist through the thickness of the photoresist to surface 88 of the substrate 82. In FIG. 4D a metal 94 (e.g. nickel) is shown as having been electroplated into the openings 92(a)-92(c). In FIG. 4E the photoresist has been removed (i.e. chemically stripped) from the substrate to expose regions of the substrate 82 which are not covered with the first metal 94. In FIG. 4F a second metal 96 (e.g. silver) is shown as having been blanket electroplated over the entire exposed portions of the substrate 82 (which is conductive) and over the first metal 94 (which is also conductive). FIG. 4G depicts the completed first layer of the structure which has resulted from the planarization of the first and second metals down to a height that exposes the first metal and sets a thickness for the first layer. In FIG. 4H the result of repeating the process steps shown in FIGS. 4B-4G several times to form a multi-layer structure is shown where each layer consists of two materials. For most applications, one of these materials is removed as shown in FIG. 4I to yield a desired 3-D structure 98 (e.g. component or device).

The various electrochemical fabrication processes used in various embodiments, alternatives, and techniques disclosed herein may be based on conformable contact masks and masking operations, proximity masks and masking operations (i.e. operations that use masks that at least partially selectively shield a substrate by their proximity to the substrate even if contact is not made), non-conformable masks and masking operations (i.e. masks and operations based on masks whose contact surfaces are not significantly conformable), and adhered masks and masking operations (masks and operations that use masks that are adhered to a substrate onto which selective deposition or etching is to occur as opposed to only being contacted to it).

Various embodiments are directed to techniques for interfacing or integrating the electrochemical fabrication of multi-layer three dimensional structures with semiconductor devices (e.g. integrated circuits) or devices produced by semiconductor manufacturing techniques. In the various embodiments presented hereafter, the semiconductor devices are provided in wafer form or die form and are used as substrates for the electrochemical fabrication build up process. These devices may be supplied with a passivation layer of adequate thickness already applied or such layers may be thickened prior to beginning the integration process.

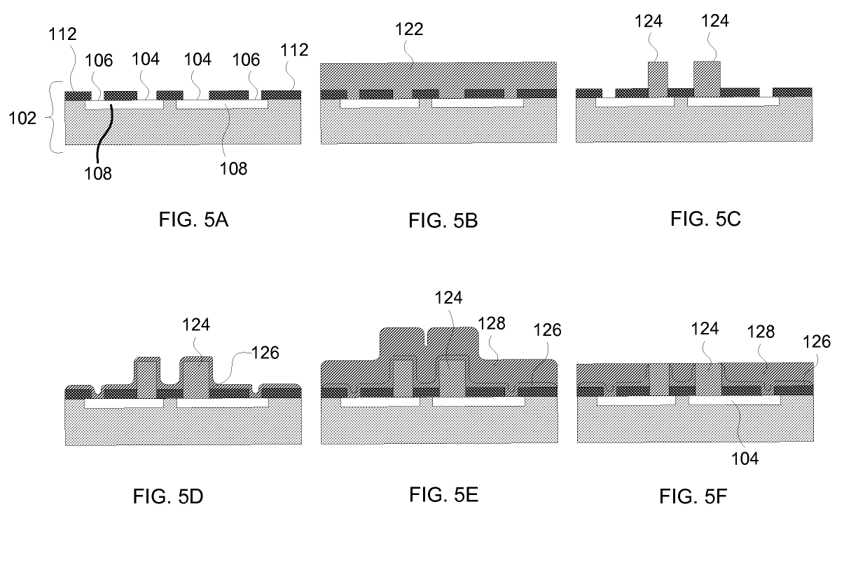

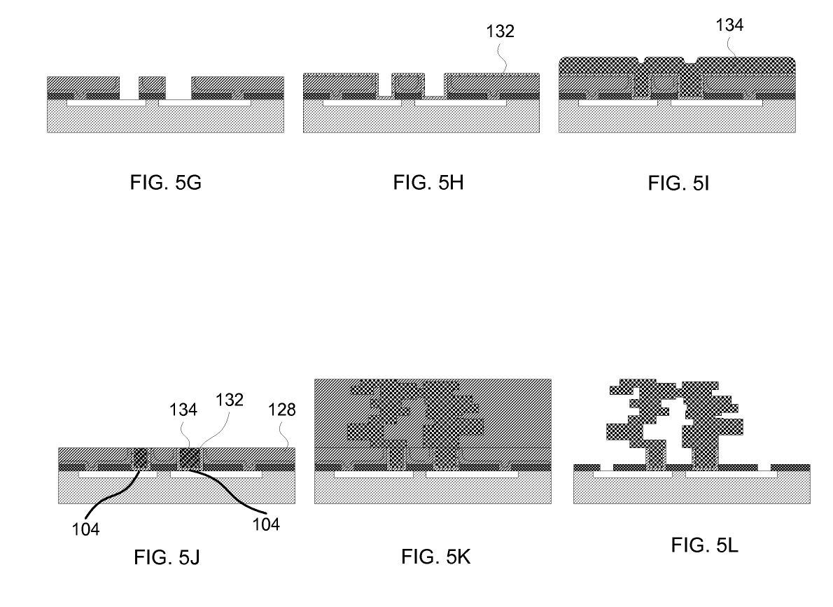

An integration process of a first preferred embodiment is depicted in FIGS. 5A-5L. A wafer 102 (or single die) is received from a standard IC fabrication process as shown in FIG. 5A. The wafer includes electronic circuitry (not shown) with interface contact pads 104 and connected bus contact pads 106 exposed. The pads are connected by runners 108 which travel under a passivation layer 112 which provides a surface of the wafer 102. Pads 104 and runners 108 may have been specifically designed with the intent of integrating to a device made by electrochemical fabrication, or alternatively pre-designed pads and interconnects that can serve as runners may be used. Other pads (not shown) may be located on wafer 102 for purposes of wire bonding, flip chip packaging, etc.

A photoresist layer 122 is applied to the upper surface of the wafer as shown in FIG. 5B. The photoresist is patterned so that the interface pads 104 remain covered with hardened photoresist 124 as shown in FIG. 5C. These covered pads are the ones to which the multilayer electrochemically fabricated structure will be interfaced.

A thin layer of copper 126 is deposited over the entire surface as shown in FIG. 5D. The deposition of the copper may, for example, occur via a physical vapor deposition process (e.g. evaporated or sputtered), via electroless copper plating, or via direct metallization (i.e. direct plating). As the adhesion between the copper and the exposed aluminum bus contact pads is not critical it may be unnecessary to apply a coating of zincate to the surface prior to copper deposition. But a zincate coating can be applied if desired or if found necessary. Furthermore, as the bus contact pads 106 are located some distance from the interface contact pads, some damage by the copper to the bus contact pads may be acceptable. If such damage is a concern, or found to be a problem, a barrier layer can be applied prior to the copper deposition. The barrier layer can then be removed toward the end of the process after removal of the copper.

Next, electrical contact is made to the thin copper coating 126 and thick copper 128 is plated as shown in FIG. 5E with a sufficient depth to allow planarization to occur.

Next the applied coatings of copper are planarized to expose the resist 124 overlaying the interface contact pads 104 as shown in FIG. 5F. The resist 124 is then removed as shown in FIG. 5G.

Next, a transition/barrier layer 132 is deposited onto the wafer as shown in FIG. 5H. The transition/barrier layer may include one or both of a coating of an adhesion promoter (such as ZINCATE) and a diffusion barrier such as titanium nitride (TiN), tantalum (Ta), and/or tantalum Nitride (TaN).

Next, electrical contact is made to the transition/barrier layer and an electrochemical fabrication structural material 134 (e.g., Ni) is plated thickly as shown in FIG. 5I.

The deposits are again planarized as shown FIG. 5J exposing the thickly plated copper 128, and removing the barrier layer 132 except near where it bounds the remaining nickel deposit 134 near the interface contact pads 104.

After again making electrical contact with the deposited metal, the electrochemical fabrication process is performed to build up the multiple layers of the three-dimensional structure. The multilayer deposition process is shown as completed in FIG. 5K. The electrochemical fabrication process may be performed in a variety of manners and may include a variety of operations, such as, for example, selective depositions, selective etchings, blanket depositions, blanket etchings, planarization operations, and the like. It may also include various cleaning, activation, passivation, and other treatment operations. The selection of operations and the ordering of the operations may vary from build process to build process or even from layer-to-layer within a single build process. Any selective deposition operations, selective etching operations, or selective treatment operations may make use of contact masks (e.g. of the conformable or non-conformable type), proximity masks, and/or adhered masks.

Next, all of the deposited copper is removed by etching as indicated in FIG. 5L. Only the structural material from the electrochemical fabrication process is left behind along with the transition/barrier layer and the wafer or (single die) material deposited between the nickel and interface contact pads 104 and covering a portion of the sides of the nickel around the interface contact pads. In this way the structure produced by electrochemical fabrication is mechanically and electrically interfaced to the metallization of the wafer.

Various alternatives to this first embodiment are possible. For example, a diffusion barrier layer could be deposited prior to the thin copper deposit 126 but after formation of the patterned resist 124. It could be removed by controlled etching as its surface area would be largely exposed compared to the amount of exposure that a coating between the interface contact pads 104 and the electrochemically fabricated structure would have. Due to this differential in exposure, it is believed that controlled etching may be performed, after layer formation is complete and the sacrificial material has been removed, to remove the barrier/transition layer from the regions of wafer or die not overlaid by the electrochemically fabricated structure without excessive damage to the contact regions between the electrochemically fabricated structure and the wafer or die.

In another alternative embodiment, a barrier layer could be applied prior to the application of the photoresist thereby obviating the need for a potential barrier layer prior to thin copper deposition of FIG. 5D and prior to the structural material deposition of FIG. 5I. In this alternative, the portion of the barrier layer uncovered after the removal of the copper can be removed.

In other alternative embodiments an adhesion transition layer may also be formed at different stages of the process.

In another alternative embodiment the runner and bus pad would not be needed. In this alternative, the interface pad is made larger than the area intended for deposition of the structural material (e.g. Ni). In this alternative, the portion of the interface contact pad 104 that is not covered by the structural material serves as the contact pad (rather than having a remote contact pad). However, since Al metallization used in the integrated circuit device may be attacked by the Cu stripper, etching of the Cu surrounding the structural material may damage the pad near the structural material. Using the runner and remote contact pad avoids this problem. Also this alternative embodiment could benefit from the previous alternative embodiment where the pre-photoresist application of a barrier layer would inhibit the attack.

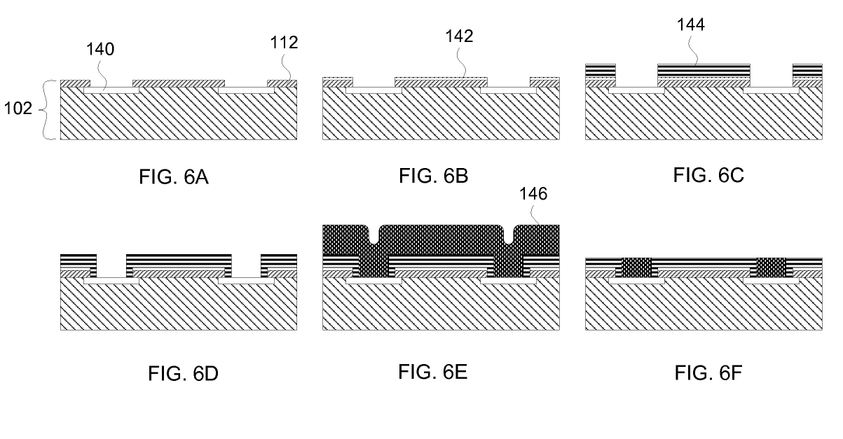

A second group of embodiments may take an alternative approach to interfacing the wafer 102 to the initial conductive deposits onto which the multiple layers of the structure will be formed. FIGS. 6A-6F show one variation of the second group of embodiments. FIG. 6A shows wafer 102 which may be prepared for the interfacing process by, for example, coating pads 140 with a material that facilitates electrodeposition or enhances adhesion (e.g., zincate treatment for aluminum pads) or adding additional passivation or barrier layers to protect wafer 102 from materials (e.g., sodium) which may be present in plating or etching baths. In FIG. 6B, a catalyst 142 for an electroless plating bath that is suitable for depositing the sacrificial material has been applied to the surface of the IC passivation layer 112. Catalyst 142 may be selectively located on the passivation layer away from contact pads 140 so that sacrificial material will not be inadvertently deposited onto the contact pads. However, if catalyst 142 coats only the perimeter of pads 140 this is acceptable and may be desirable in some embodiments. Catalyst 142 may be selectively applied, for example, by contacting the protruding surface of passivation layer 112 with a plate or stamp coated with a thin film of catalyst 142, or by selectively dispensing catalyst 142 (e.g. via an ink jet or an extrusion head).

In FIG. 6C, sacrificial material 144 has been deposited onto the catalyzed surface, which is assumed to be confined to the top surface of passivation layer 112. In FIG. 6D the deposit has been continued until material 144 ‘mushrooms’ out and makes contact with the perimeter of pads 140. Once such contact is made, pads 140 are in electrical contact with one another and with material 144 and can be electrodeposited with another material. In FIG. 6E, structural material has been electrodeposited onto pads 140. Finally, in FIG. 6F, sacrificial and structural materials have been planarized so as to create a relatively flat and smooth substrate (as in FIG. 5J) which is suitable as a starting layer for further electrochemical fabrication operations where the starting layer includes regions of sacrificial material (e.g., copper) and regions of structural material (e.g., nickel). In other words, the starting layer includes a structural material in regions that contact the pads and are intended to be electrically active, while a temporary presence of copper is located in all other regions.

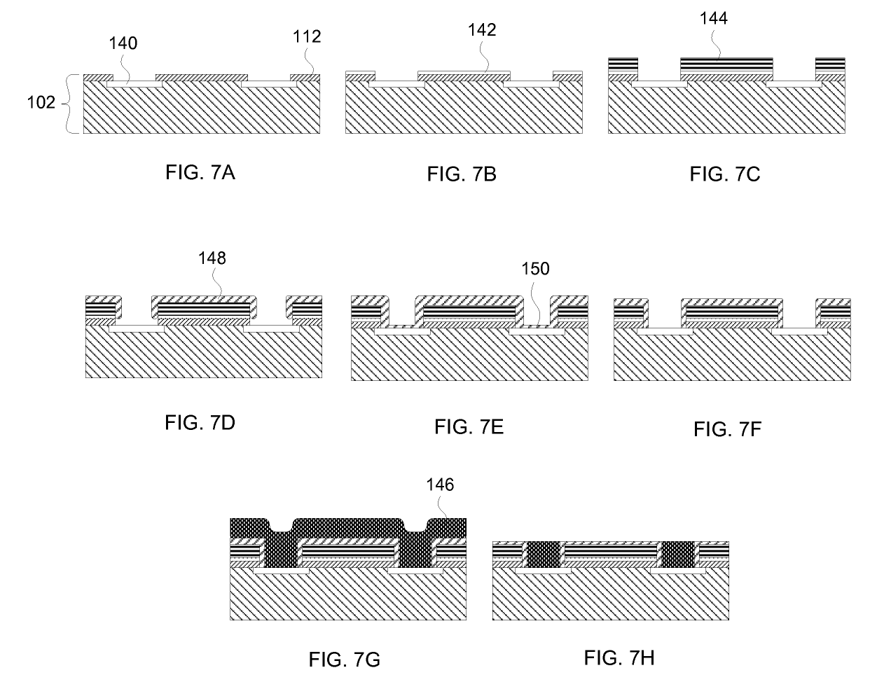

FIGS. 7A-7H show another embodiment of the second group of embodiments. The initial operations (FIGS. 7A-7C) are identical to those of FIGS. 6A-6C already described. Again, if catalyst 142 coats the perimeter of pads 140, this may be acceptable. In FIG. 7D additional sacrificial material 148 has been electrodeposited over sacrificial material 144 already deposited by electroless deposition in FIG. 7C, with material 144 serving as a seed layer. In FIG. 7E the electrodeposition process is continued such that the electrodeposited material ‘mushrooms’ out far enough to reach contact pads 140. Once contact has been established with pad 140, a relatively thin deposit 150 of material 148 forms over the entire surface of pads 140 as shown in FIG. 7E. In FIG. 7F, thin deposit 150 has been etched to re-expose pads 140. In FIG. 7G, structural material 146 is deposited, and in FIG. 7H, the two materials are planarized, with the wafer ready to receive the first layer in an electrochemical fabrication process.

It is possible that deposition of extra material 148 as performed by the operation that let to the state depicted in FIG. 7D, will not occur in some electrically isolated regions of material 144 (instead it is possible that material 146 will begin depositing there once deposition thickness of material on the pads reaches a level that contacts the edge of material 144). This failure to deposit, or to deposit the wrong material may be problematic in some embodiments depending on how and where material will be deposited in the formation of subsequent layers, requirements on electrical isolation, and/or on the planarization level chosen when trimming this first integrating layer. As shown, in FIG. 7H the plane of planarization passes through material 148 and is above material 144 and thus if material 148 did not exist over some regions of material 144 an non-planar surface may result, or if material 146 were deposited there it would remain in the final structure. However, in some alternative embodiments, these problems may be avoided by making the level of planarization lower such that it passes through material 144 and in such alternatives the lack of material 148 or inadvertent existence of material 146 in some regions would not be problematic.

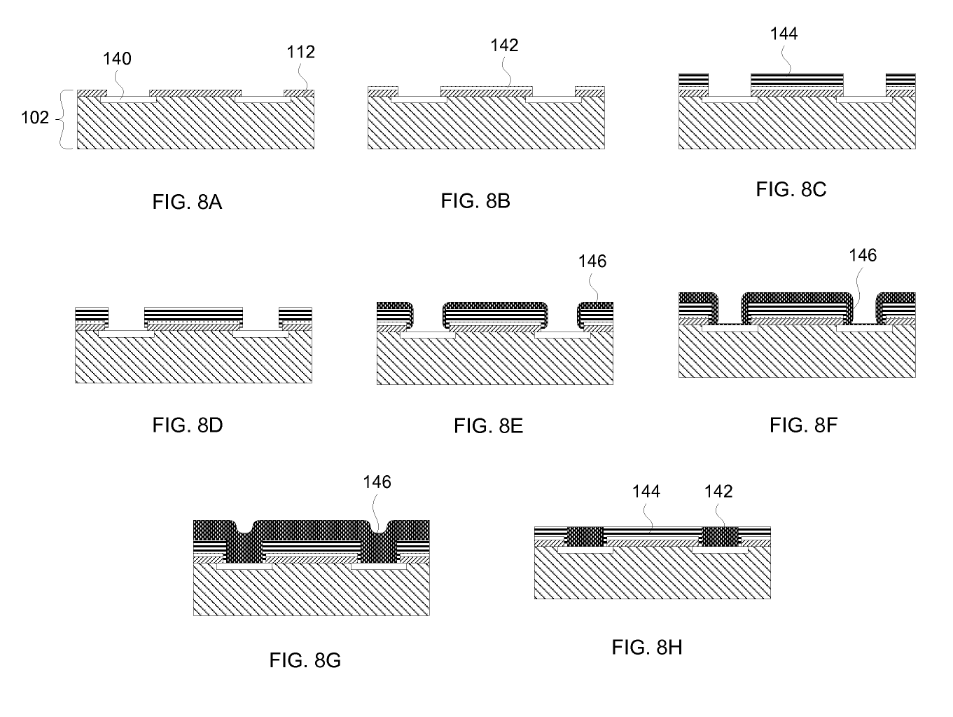

FIGS. 8A-8H illustrate another embodiment of the second group of embodiments. FIGS. 8A-8D show processing identical to that of FIGS. 6A-6D, except that in FIG. 8D, although material 144 has started to ‘mushroom’ out, the deposit has not been continued long enough to allow material 144 to make contact with pads 140. If desired, material 144 may be thickened by electrodepositing additional sacrificial material on top of it. In FIG. 8E, structural material 146 has been electrodeposited over electroless-deposited material 144 (except in any regions of material 146 that might be electrically isolated). In FIG. 8F, the electrodeposition of structural material 146 has been continued long enough for the electrodeposited material to ‘mushroom’ out far enough to touch the contact pads 140. Once this contact has been established with pads 140, a layer of material 146 begins to cover the entire surface of pads 140 and this continues to grow in thickness, as shown in FIG. 8G. Finally, FIG. 8H shows the result of planarization, with the wafer ready to receive the first layer in an electrochemical fabrication process. In this embodiment, initial failure to deposit structural material 146 over some regions of material 144 is not problematic since once plating to the pads begins and the deposition height grows sufficiently to cause contact with any unplated sacrificial material, deposition of structural material over entire region of unplated sacrificial material will begin immediately.

In some alternative embodiments, over depositing sacrificial material with structural material may be avoided or minimized by use of masking operations or other surface treatment operations such that the structural material is essentially selectively deposited. After such selective deposition of structural material, planarization may occur if desired or needed or a subsequent selective or blanket deposition of sacrificial material may occur to increase its height prior to any planarization operation or prior to initiating formation of a subsequent layer of material. In some embodiments, where barrier layers or adhesion layers are applied prior to the plating of structural material into pockets formed in sacrificial material, the mushrooming effect noted above may not be necessary as the presence of the barrier or adhesion layers may provided the required conductivity

In some alternative embodiments, the IC passivation layer may be thickened prior to performing electroless deposition of sacrificial material, e.g., by coating with a patterned polyimide or photoresist. This thickening may be useful in limiting the spread of plated copper from the passivation layer over the edges of the passivation layer and onto the contact pads.

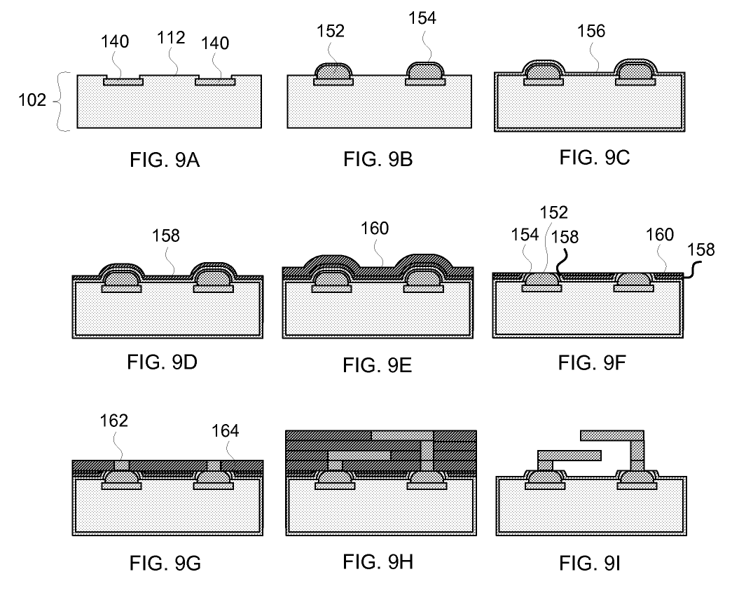

A one variation of a third group of embodiments, is exemplified in FIGS. 9A-9I, and may use electroless nickel plating or other methods commonly used to produce bumps on semiconductor wafers (e.g., gold plating, ball bumping, stud bumping) to get an initial deposit of the structural material onto contact pads of an IC. The method assumes that the material of the bumps, balls, or studs formed on the wafer is compatible with and will not substantially be attacked by the etchant used to remove the sacrificial material from the electrochemically fabricated structure. An example of such an embodiment, assuming the use of electroless nickel bumping, includes the following operations:

1. Receive a wafer (or single die) 102 from a standard IC fabrication process (FIG. 9A).

2. Assuming all exposed contact pads 140 are to be contact locations for electrochemical fabrication, an electroless nickel deposition is applied to the contact pads (FIG. 9B) by a process along the lines of that being commercialized by Pac Tech GmbH which may include, for example:
Cleaning wafer 102,
Applying a zincate treatment to the contact pads, for example by:
   Placing the wafer into a zincate solution for less than about 3 minutes and then rinsing in deionized water.
   Repeating the placing and rinsing as necessary or desired.
Placing the wafer into a nickel solution such as 8-10% NiP at 85° C. for 12-15 minutes to form nickel bumps 152 of at least 5 μm thickness.

The wafer may be left in longer to increase the thickness of the bumps which may make planarization easier in a subsequent operation.
After plating, rinse in DI water.
Normally, a gold coating 154 is applied over the nickel bump for oxidation resistance but this may be omitted.
   If not all of the contact pads will be connection locations for the electrochemically fabricated structure then the non-connection pads should be protected from the electroless deposition. This may be accomplished for example by the photoresist process set forth in the embodiment of FIGS. 5A-5L. or by use of a contact mask (e.g. a conformable contact mask) or by use of other adhered masking techniques.

3. As shown in FIG. 9C, if desired or necessary (e.g., to avoid damage to the wafer from plating or etching chemicals), the passivation layer of the IC may be enhanced by application of an additional passivation or a barrier layer 156 such as titanium nitride (TiN), tantalum (Ta), tantalum nitride (TaN), and/or polyimide. If the layer 156 is conductive, or if the contact pads on which connection between the wafer and the electrochemically fabricated structure will be based are protected (e.g., using the photoresist process set forth in the embodiment of FIGS. 5A-5L), then the passivation layer may be applied prior to the operation leading to FIG. 9B. As shown in FIG. 9D, a thin plating base 158 of sacrificial material (here assumed to be copper) is deposited, e.g. by sputtering, over the entire surface of the integrated circuit. In other embodiments, deposition by direct metallization and associated plating or by an electroless process may occur.

4. Electrical contact is made to the thin plating base 158 and then thick copper 160 is electroplated as shown in FIG. 9E.

5. As shown in FIG. 9F, the wafer is then planarized to reveal flattened nickel bumps 152 surrounded by and co-planar with flat sacrificial copper 158 and 160, thus forming a suitable substrate for continued electrochemical fabrication of a multilayer structure. Prior to planarization, the wafer is fixtured if required such that its top surface and/or the top of bumps 152 are substantially planar. The plane of planarization is chosen so as to remove the coating 156 (which may be insulating or of a material not desired in the final structure) from bumps 152. If some contact pads were protected by a nonconductive barrier, the nonconductive barrier may have been removed prior to the deposition of FIG. 9C or alternatively the protection could have remained in place particularly if it was of a thickness that positioned its surface below that of the planarization level. In these alternatives, the barrier may remain in place until structure formation is complete and the sacrificial material removed after which the barrier material may be removed.

6. FIG. 9G shows a first layer consisting of structural material 162 (e.g., nickel) and sacrificial material 164 (e.g. copper) that have been formed using electrochemical fabrication techniques. Note that at least one of the electrodeposited materials (as shown, the copper) may need to ‘mushroom’ slightly over thin exposed edge 164 of layer 156 if the latter is non-conductive.

7. As shown in FIG. 9H, successive layers are then formed over the first layer via electrochemical fabrication techniques.

8. FIG. 9I shows the resulting multi-layer IC-integrated structure after the sacrificial material (e.g. copper) is etched with the integrated circuit being protected by the deposited nickel and the optionally applied layer 156.

9. Finally, if layer 156 was applied and it is conductive, then it must be removed (not shown), e.g., by wet or dry etching. If the barrier was non-conductive it may remain assuming it isn't undesirable in the final device or that it isn't covering contact pads that are needed for other operations. If the barrier layer is conductive and exists between the structural material (e.g. nickel) and the contact pads, reasonable control of the etching process will ensure that no significant damage to the interface occurs as the exposed portions of the barrier are removed.

A fourth group of embodiments may start off by protecting the contact pads with a dielectric masking material, such as a contact mask or adhered mask. While the pads are protected, direct metallization and plating (e.g., using copper) of the surface of the passivation layer may be performed. After this, a contact mask (if used) may be removed and then structural material plated (e.g. nickel). The plating will cover the contact pads once any dielectric gap between the surface of the passivation layer and the contact pads is bridged by the mushrooming deposition of structural material. If no gap exists, then plating to the pads will begin immediately along with the deposition over the passivation layer.

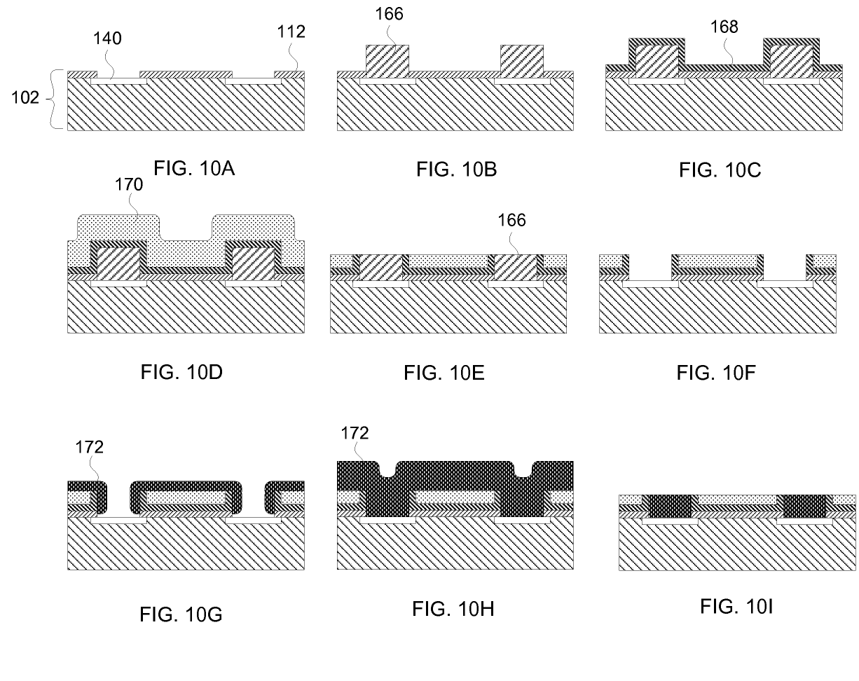

One example embodiment from the fourth group of embodiments uses an adhered mask and is explained with the aid of FIGS. 10A-10I. FIG. 10A shows a wafer 102 ready to process. In FIG. 10B, an adhered mask material 166 has been applied and patterned. In FIG. 10C, the wafer has been treated with a direct metallization treatment as is known to the art (e.g., the shadow process from Electrochemicals USA) to form platable layer 168. Alternatively, a platable layer can be applied using an electroless process or using a sputtered or evaporated seed layer. In FIG. 10D, a thick deposit of sacrificial material 170 (e.g. copper) has been deposited. In FIG. 10E, wafer 102 has been planarized to expose mask material 166, allowing its removal as shown in FIG. 10F. In FIG. 10G, structural material 172 (e.g., nickel) has started to be plated over the wafer (note that electrically isolated regions may not be plated or at least not plated initially) where it is shown as beginning to ‘mushroom’ down towards pads 140. Note that this assumes that passivation 112 represents a significant gap over which material 172 must ‘mushroom’. In FIG. 10H, material 172 has continued to be deposited, first mushrooming to contact pads 140, then growing upwards from pads 140 which are conductive, until a thick layer has been deposited. FIG. 10I shows the wafer after planarization and ready to deposit the first layer in an electrochemical fabrication process.

In some alternative embodiments, the direct metallization or direct plating process may be replaced by a sputtering process, an electroless deposition process, or the like. In some embodiments it may be possible to use spray metal deposition to achieve an initial layer of conductive material such as one of the processes described in U.S. Provisional Patent Application No. 60/435,324 described herein elsewhere.

In other alternative embodiments, if necessary, some form of intermediate coating may be applied between conductive pads on the IC (e.g. aluminum pads) and the metal (e.g. nickel) to be deposited thereon. Such coatings may include diffusion barrier materials (e.g. TiN, Ta, and/or TaN, and the like) and/or adhesion promoters (e.g. via phosphoric acid anodizing, stannate immersion, zincate immersion, and the like).

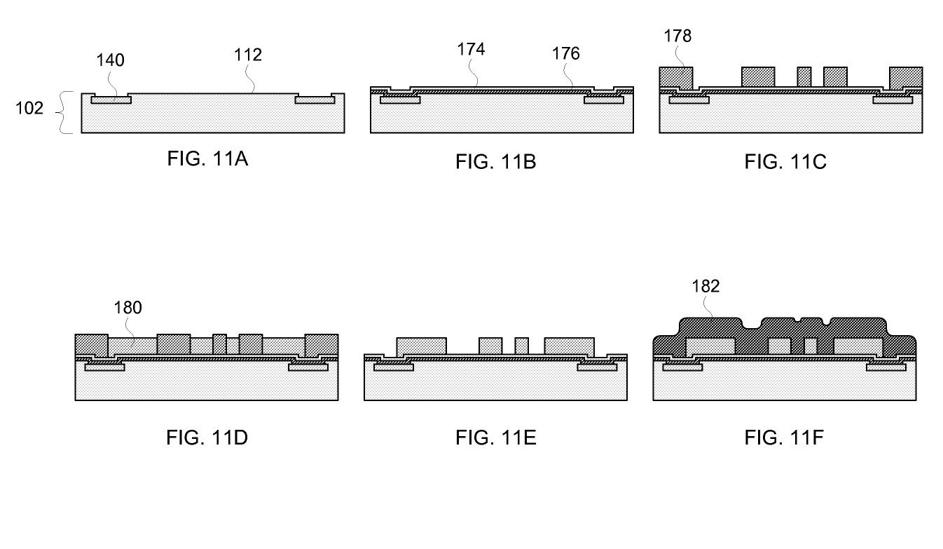

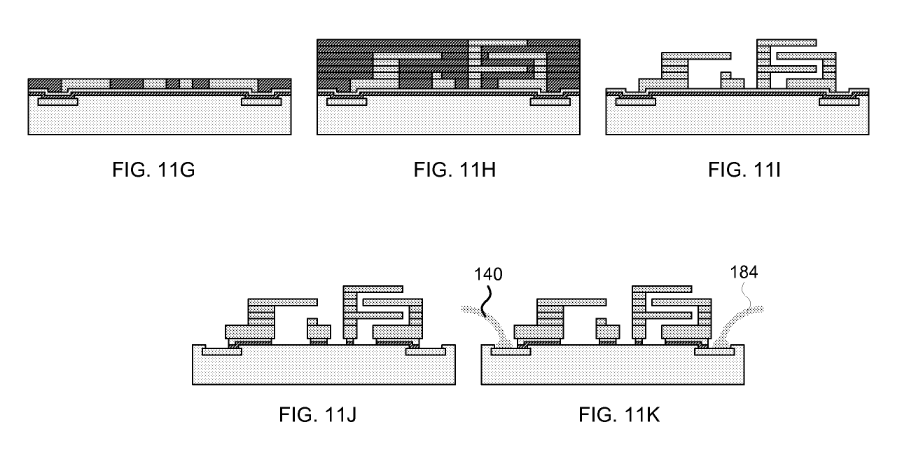

A fifth group of embodiments, illustrated in FIGS. 11A-11K, allows structures produced using electrochemical fabrication to be anchored and mechanically secured to any region of a wafer, whether pad or passivation. FIG. 11A shows a wafer 102 ready for processing. Wafer 102 may be coated with a passivation film (e.g., polyimide, not shown) into which apertures are formed corresponding to pads 140 which are to be interfaced to the electrochemically-fabricated structure; this film can eventually be removed if desired.

In FIG. 11B, a plating seed layer 174 (e.g., gold) has been applied to the surface of wafer 102. If necessary, adhesion layer 176 (e.g., titanium or chromium) can be applied first (as is shown) to improve adhesion of seed layer 174. If necessary, pads 140 can first be coated with a material that will protect them against the eventual etch of seed layer 174 and/or adhesion layer 176.

In FIG. 11C, a patterned layer of masking material 178 (e.g., photoresist) has been produced on wafer 102. In FIG. 11D, structural material 180 (e.g., nickel) has been selectively deposited (e.g., by electroplating) onto seed layer 174 and in FIG. 11E, masking material 178 has been removed. In FIG. 11F, sacrificial material 182 (e.g., copper) has been blanket-deposited (e.g., by electroplating) over wafer 102. Both materials 180 and 182 are deposited in sufficient thickness to allow for subsequent planarization; FIG. 11G shows the result of this planarization step which leaves the wafer ready to deposit the first layer in an electrochemical fabrication process.

In FIG. 11H, multiple layers have been fabricated using an electrochemical fabrication process, and in FIG. 11I, after all layers have been formed, sacrificial material 182 has been removed (e.g., by etching). In FIG. 11J, seed layer 174 and (if used) adhesion layer 176 have been partially etched using a controlled etch so as to remove these materials other than where protected by overlying structural material 176. In FIG. 11K, bonding wires 184 have been attached to regions of pads 140 that have no electrochemically-fabricated structure overlying them, if made large enough. In this way, some pads 140 can serve two purposes: both to electrically connect the integrated device to the outside world, for example through wire bonding (as shown) or flip chip (not shown), and to electrically and mechanically connect to the structure formed by electrochemical fabrication. Alternatively, some pads can be dedicated to forming off-chip electrical connections and some dedicated to connecting to the electrochemically-fabricated structure, with interconnects between such pads provided below passivation layer 112 as required. According to this fifth group of embodiments, structures produced by electrochemical fabrication may have anchors to the wafer that partially or entirely overlap pads 140, or the anchors may be entirely decoupled from pads 140 and only anchored to wafer passivation 112. Note that at least a portion of the function of the electrochemically-fabricated structure shown in FIG. 11 may be to redistribute the pads 140 into a new configuration, e.g., one more suitable for interfacing the IC to the outside world.

Though the present embodiments have focused on electrochemically fabricated structures containing a structural material of nickel and a sacrificial material of copper, other embodiments are possible where different structural and/or sacrificial materials are used. Furthermore, interfacing between a wafer or die and electrochemically produced structures utilizing different structural and/or sacrificial materials may occur via the nickel and copper materials exemplified herein or may occur via the different materials according to the generalized applicability of the processes set forth herein to those materials. Still other embodiments will be apparent to those of skill in the art upon review of the teachings herein, such as processes that involves various combinations of the operations used in the different embodiments disclosed herein.

Various alternatives to and variations of the above noted embodiments exist. In some alternative embodiments, the structural material of choice is nickel and the sacrificial material of choice is copper, and in other embodiments other or additional structural materials may be chosen and other or additional sacrificial materials may be chosen.

The patent applications set forth below are hereby incorporated by reference herein as if set forth in full. The gist of each patent application is included in the table to aid the reader in finding specific types of teachings. It is not intended that the incorporation of subject matter be limited to those topics specifically indicated, but instead the incorporation is to include all subject matter found in these applications. The teachings in these incorporated applications can be combined with the teachings of the instant application in many ways: For example, enhanced methods of producing structures may be derived from the combination of teachings, enhanced structures may be obtainable, enhanced apparatus may be derived, and the like.

U.S. patent application Ser. No. 09/488,142, filed Jan. 20, 2000, and entitled “An Apparatus for Electrochemical Fabrication Comprising A Conformable Mask” is a divisional of the application that led to the above noted '630 patent. This application describes the basics of conformable contact mask plating and electrochemical fabrication including various alternative methods and apparatus for practicing EFAB as well as various methods and apparatus for constructing conformable contact masks.

U.S. Patent Application No. 60/415,374, filed on Oct. 1, 2002, and entitled “Monolithic Structures Including Alignment and/or Retention Fixtures for Accepting Components” is generally directed to permanent or temporary alignment and/or retention structures for receiving multiple components. The structures are preferably formed monolithically via a plurality of deposition operations (e.g. electrodeposition operations). The structures typically include two or more positioning fixtures that control or aid in the positioning of components relative to one another, such features may include (1) positioning guides or stops that fix or at least partially limit the positioning of components in one or more orientations or directions, (2) retention elements that hold positioned components in desired orientations or locations, and (3) positioning and/or retention elements that receive and hold adjustment modules into which components can be fixed and which in turn can be used for fine adjustments of position and/or orientation of the components.

U.S. Patent Application No. 60/464,504, filed on Apr. 21, 2003, and entitled “Methods of Reducing Discontinuities Between Layers of Electrochemically Fabricated Structures” is generally directed to various embodiments providing electrochemical fabrication methods and apparatus for the production of three-dimensional structures from a plurality of adhered layers of material including operations or structures for reducing discontinuities in the transitions between adjacent layers. Some embodiments improve the conformance between a size of produced structures (especially in the transition regions associated with layers having offset edges) and the intended size of the structure as derived from original data representing the three-dimensional structures. Some embodiments make use of selective and/or blanket chemical and/or electrochemical deposition processes, selective and or blanket chemical and/or electrochemical etching process, or combinations thereof. Some embodiments make use of multi-step deposition or etching operations during the formation of single layers.

U.S. Patent Application No. 60/468,979, filed on May 7, 2003, and entitled “EFAB With Selective Transfer Via Instant Mask” is generally directed to three-dimensional structures that are electrochemically fabricated by depositing a first material onto previously deposited material through voids in a patterned mask where the patterned mask is at least temporarily adhered to a substrate or previously formed layer of material and is formed and patterned onto the substrate via a transfer tool patterned to enable transfer of a desired pattern of precursor masking material. In some embodiments the precursor material is transformed into masking material after transfer to the substrate while in other embodiments the precursor is transformed during or before transfer. In some embodiments layers are formed one on top of another to build up multi-layer structures. In some embodiments the mask material acts as a build material while in other embodiments the mask material is replaced each layer by a different material which may, for example, be conductive or dielectric.

U.S. Patent Application No. 60/469,053, filed on May 7, 2003, and entitled “Three-Dimensional Object Formation Via Selective Inkjet Printing & Electrodeposition” is generally directed to three-dimensional structures that are electrochemically fabricated by depositing a first material onto previously deposited material through voids in a patterned mask where the patterned mask is at least temporarily adhered to previously deposited material and is formed and patterned directly from material selectively dispensed from a computer controlled dispensing device (e.g. an ink jet nozzle or array or an extrusion device). In some embodiments layers are formed one on top of another to build up multi-layer structures. In some embodiments the mask material acts as a build material while in other embodiments the mask material is replaced each layer by a different material which may, for example, be conductive or dielectric.

U.S. patent application Ser. No. 10/271,574, filed on Oct. 15, 2002, and entitled “Methods of and Apparatus for Making High Aspect Ratio Microelectromechanical Structures” is generally directed to various embodiments for forming structures (e.g. HARMS-type structures) via an electrochemical extrusion (ELEX™) process. Preferred embodiments perform the extrusion processes via depositions through anodeless conformable contact masks that are initially pressed against substrates that are then progressively pulled away or separated as the depositions thickens. A pattern of deposition may vary over the course of deposition by including more complex relative motion between the mask and the substrate elements. Such complex motion may include rotational components or translational motions having components that are not parallel to an axis of separation. More complex structures may be formed by combining the ELEX™ process with the selective deposition, blanket deposition, planarization, etching, and multi-layer operations of EFAB™.

U.S. Patent Application No. 60/435,324, filed on Dec. 20, 2002, and entitled “EFAB Methods and Apparatus Including Spray Metal or Powder Coating Processes”, is generally directed to techniques for forming structures via a combined electrochemical fabrication process and a thermal spraying process. In a first set of embodiments, selective deposition occurs via conformable contact masking processes and thermal spraying is used in blanket deposition processes to fill in voids left by selective deposition processes. In a second set of embodiments, selective deposition via a conformable contact masking is used to lay down a first material in a pattern that is similar to a net pattern that is to be occupied by a sprayed metal. In these embodiments a second material is blanket deposited to fill in the voids left in the first pattern, the two depositions are planarized to a common level that may be somewhat greater than a desired layer thickness, the first material is removed (e.g. by etching), and a third material is sprayed into the voids left by the etching operation. The resulting depositions in both the first and second sets of embodiments are planarized to a desired layer thickness in preparation for adding additional layers to form three-dimensional structures from a plurality of adhered layers. In other embodiments, additional materials may be used and different processes may be used.

U.S. Patent Application No. 60/429,483, filed on Nov. 26, 2002, and entitled “Multi-cell Masks and Methods and Apparatus for Using Masks to Form Three-Dimensional Structures” is generally directed to multilayer structures that are electrochemically fabricated via depositions of one or more materials in a plurality of overlaying and adhered layers. Selectivity of deposition is obtained via a multi-cell controllable mask. Alternatively, net selective deposition is obtained via a blanket deposition and a selective removal of material via a multi-cell mask. Individual cells of the mask may contain electrodes comprising depositable material or electrodes capable of receiving etched material from a substrate. Alternatively, individual cells may include passages that allow or inhibit ion flow between a substrate and an external electrode and that include electrodes or other control elements that can be used to selectively allow or inhibit ion flow and thus inhibiting significant deposition or etching.

U.S. Patent Application No. 60/429,484, filed on Nov. 26, 2002, and entitled “Non-Conformable Masks and Methods and Apparatus for Forming Three-Dimensional Structures” is generally directed to electrochemical fabrication used to form multilayer structures (e.g. devices) from a plurality of overlaying and adhered layers. Masks, that are independent of a substrate to be operated on, are generally used to achieve selective patterning. These masks may allow selective deposition of material onto the substrate or they may allow selective etching of a substrate whereafter the created voids may be filled with a selected material that may be planarized to yield in effect a selective deposition of the selected material. The mask may be used in a contact mode or in a proximity mode. In the contact mode the mask and substrate physically mate to form substantially independent process pockets. In the proximity mode, the mask and substrate are positioned sufficiently close to allow formation of reasonably independent process pockets. In some embodiments, masks may have conformable contact surfaces (i.e. surfaces with sufficient deformability that they can substantially conform to surface of the substrate to form a seal with it) or they may have semi-rigid or even rigid surfaces. Post deposition etching operations may be performed to remove flash deposits (thin undesired deposits).

U.S. patent application Ser. No. 10/309,521, filed on Dec. 3, 2002, and entitled “Miniature RF and Microwave Components and Methods for Fabricating Such Components” is generally directed to RF and microwave radiation directing or controlling components that may be monolithic, that may be formed from a plurality of electrodeposition operations and/or from a plurality of deposited layers of material, that may include switches, inductors, antennae, transmission lines, filters, and/or other active or passive components. Components may include non-radiation-entry and non-radiation-exit channels that are useful in separating sacrificial materials from structural materials. Preferred formation processes use electrochemical fabrication techniques (e.g. including selective depositions, bulk depositions, etching operations and planarization operations) and post-deposition processes (e.g. selective etching operations and/or back filling operations).

U.S. Patent Application No. 60/468,977, filed on May 7, 2003, and entitled “Method for Fabricating Three-Dimensional Structures Including Surface Treatment of a First Material in Preparation for Deposition of a Second Material” is generally directed to a method of fabricating three-dimensional structures from a plurality of adhered layers of at least a first and a second material wherein the first material is a conductive material and wherein each of a plurality of layers includes treating a surface of a first material prior to deposition of the second material. The treatment of the surface of the first material either (1) decreases the susceptibility of deposition of the second material onto the surface of the first material or (2) eases or quickens the removal of any second material deposited on the treated surface of the first material. In some embodiments the treatment of the first surface includes forming a dielectric coating over the surface while the deposition of the second material occurs by an electrodeposition process (e.g. an electroplating or electrophoretic process).

U.S. patent application Ser. No. 10/387,958, filed on Mar. 13, 2003, and entitled “Electrochemical Fabrication Method and Apparatus for Producing Three-Dimensional Structures Having Improved Surface Finish” is generally directed to an electrochemical fabrication process that produces three-dimensional structures (e.g. components or devices) from a plurality of layers of deposited materials wherein the formation of at least some portions of some layers are produced by operations that remove material or condition selected surfaces of a deposited material. In some embodiments, removal or conditioning operations are varied between layers or between different portions of a layer such that different surface qualities are obtained. In other embodiments varying surface quality may be obtained without varying removal or conditioning operations but instead by relying on differential interaction between removal or conditioning operations and different materials encountered by these operations.

U.S. patent application Ser. No. 10/434,494, filed on May 7, 2003, and entitled “Methods and Apparatus for Monitoring Deposition Quality During Conformable Contact Mask Plating Operations” is generally directed to a electrochemical fabrication (e.g. EFAB) processes and apparatus are disclosed that provide monitoring of at least one electrical parameter (e.g. voltage) during selective deposition where the monitored parameter is used to help determine the quality of the deposition that was made. If the monitored parameter indicates that a problem occurred with the deposition, various remedial operations may be undertaken to allow successful formation of the structure to be completed.

U.S. patent application Ser. No. 10/434,289, filed on May 7, 2003, and entitled “Conformable Contact Masking Methods and Apparatus Utilizing In Situ Cathodic Activation of a Substrate” is generally directed to a electroplating processes (e.g. conformable contact mask plating and electrochemical fabrication processes) that includes in situ activation of a surface onto which a deposit will be made. At least one material to be deposited has an effective deposition voltage that is higher than an open circuit voltage, and wherein a deposition control parameter is capable of being set to such a value that a voltage can be controlled to a value between the effective deposition voltage and the open circuit voltage such that no significant deposition occurs but such that surface activation of at least a portion of the substrate can occur. After making electrical contact between an anode, that comprises the at least one material, and the substrate via a plating solution, applying a voltage or current to activate the surface without any significant deposition occurring, and thereafter without breaking the electrical contact, causing deposition to occur.

U.S. patent application Ser. No. 10/434,294, filed on May 7, 2003, and entitled “Electrochemical Fabrication Methods With Enhanced Post Deposition Processing” is generally directed to a electrochemical fabrication process for producing three-dimensional structures from a plurality of adhered layers is provided where each layer comprises at least one structural material (e.g. nickel) and at least one sacrificial material (e.g. copper) that will be etched away from the structural material after the formation of all layers have been completed. A copper etchant containing chlorite (e.g. Enthone C-38) is combined with a corrosion inhibitor (e.g. sodium nitrate) to prevent pitting of the structural material during removal of the sacrificial material. A simple process for drying the etched structure without the drying process causing surfaces to stick together includes immersion of the structure in water after etching and then immersion in alcohol and then placing the structure in an oven for drying.

U.S. patent application Ser. No. 10/434,315, filed on May 7, 2003, and entitled “Methods of and Apparatus for Molding Structures Using Sacrificial Metal Patterns” is generally directed to molded structures, methods of and apparatus for producing the molded structures. At least a portion of the surface features for the molds are formed from multilayer electrochemically fabricated structures (e.g. fabricated by the EFAB™ formation process), and typically contain features having resolutions within the 1 to 100 μm range. The layered structure is combined with other mold components, as necessary, and a molding material is injected into the mold and hardened. The layered structure is removed (e.g. by etching) along with any other mold components to yield the molded article. In some embodiments portions of the layered structure remain in the molded article and in other embodiments an additional molding material is added after a partial or complete removal of the layered structure.

U.S. patent application Ser. No. 10/434,493, filed on May 7, 2003, and entitled “Electrochemically Fabricated Structures Having Dielectric or Active Bases and Methods of and Apparatus for Producing Structures” is generally directed to multilayer structures that are electrochemically fabricated on a temporary (e.g. conductive) substrate and are thereafter bonded to a permanent (e.g. dielectric, patterned, multi-material, or otherwise functional) substrate and removed from the temporary substrate. In some embodiments, the structures are formed from top layer to bottom layer, such that the bottom layer of the structure becomes adhered to the permanent substrate, while in other embodiments the structures are form from bottom layer to top layer and then a double substrate swap occurs. The permanent substrate may be a solid that is bonded (e.g. by an adhesive) to the layered structure or it may start out as a flowable material that is solidified adjacent to or partially surrounding a portion of the structure with bonding occurs during solidification. The multilayer structure may be released from a sacrificial material prior to attaching the permanent substrate or it may be released after attachment.

U.S. patent application Ser. No. 10/434,103, filed on May 7, 2003, and entitled “Electrochemically Fabricated Hermetically Sealed Microstructures and Methods of and Apparatus for Producing Structures” is generally directed to multilayer structures that are electrochemically fabricated from at least one structural material (e.g. nickel), at least one sacrificial material (e.g. copper), and at least one sealing material (e.g. solder). In some embodiments, the layered structure is made to have a desired configuration which is at least partially and immediately surrounded by sacrificial material which is in turn surrounded almost entirely by structural material. The surrounding structural material includes openings in the surface through which etchant can attack and remove trapped sacrificial material found within. Sealing material is located near the openings. After removal of the sacrificial material, the box is evacuated or filled with a desired gas or liquid. Thereafter, the sealing material is made to flow, seal the openings, and resolidify. In other embodiments, a post-layer formation lid or other enclosure completing structure is added.

U.S. patent application Ser. No. 10/434,497, filed on May 7, 2003, and entitled “Multistep Release Method for Electrochemically Fabricated Structures” is generally directed to multilayer structures that are electrochemically fabricated from at least one structural material (e.g. nickel), that is configured to define a desired structure and which may be attached to a substrate, and from at least one sacrificial material (e.g. copper) that surrounds the desired structure. After structure formation, the sacrificial material is removed by a multi-stage etching operation. In some embodiments sacrificial material to be removed may be located within passages or the like on a substrate or within an add-on component. The multi-stage etching operations may be separated by intermediate post processing activities, they may be separated by cleaning operations, or barrier material removal operations, or the like. Barriers may be fixed in position by contact with structural material or with a substrate or they may be solely fixed in position by sacrificial material and are thus free to be removed after all retaining sacrificial material is etched.

U.S. patent application Ser. No. 10/434,519, filed on May 7, 2003, and entitled “Methods of and Apparatus for Electrochemically Fabricating Structures Via Interlaced Layers or Via Selective Etching and Filling of Voids” is generally directed to multi-layer structures that are electrochemically fabricated by depositing a first material, selectively etching the first material (e.g. via a mask), depositing a second material to fill in the voids created by the etching, and then planarizing the depositions so as to bound the layer being created and thereafter adding additional layers to previously formed layers. The first and second depositions may be of the blanket or selective type. The repetition of the formation process for forming successive layers may be repeated with or without variations (e.g. variations in: patterns; numbers or existence of or parameters associated with depositions, etchings, and or planarization operations; the order of operations, or the materials deposited). Other embodiments form multi-layer structures using operations that interlace material deposited in association with some layers with material deposited in association with other layers.

Various other embodiments exist. Some of these embodiments may be based on a combination of the teachings herein with various teachings incorporated herein by reference. Some embodiments may not use any blanket deposition process and/or they may not use a planarization process. Some embodiments may involve the selective deposition of a plurality of different materials on a single layer or on different layers. Some embodiments may use blanket depositions processes that are not electrodeposition processes. Some embodiments may use selective deposition processes on some layers that are not conformable contact masking processes and are not even electrodeposition processes. Some embodiments may use nickel as a structural material while other embodiments may use different materials such as gold, silver, or any other electrodepositable materials that can be separated from the copper and/or some other sacrificial material. Some embodiments may use copper as the structural material with or without a sacrificial material. Some embodiments may remove a sacrificial material while other embodiments may not. In some embodiments, the depth of deposition will be enhanced by pulling the conformable contact mask away from the substrate as deposition is occurring in a manner that allows the seal between the conformable portion of the CC mask and the substrate to shift from the face of the conformal material to the inside edges of the conformable material.

In view of the teachings herein, many further embodiments, alternatives in design and uses of the invention will be apparent to those of skill in the art. As such, it is not intended that the invention be limited to the particular illustrative embodiments, alternatives, and uses described above but instead that it be solely limited by the claims presented hereafter.

We claim:

1. An electrochemical fabrication process for producing a three-dimensional structure from at least one structural material on a semiconductor wafer, or portion thereof, from a plurality of adhered layers, the process comprising:
(A) supplying a substrate which comprises a semiconductor wafer or portion thereof containing electrical circuitry and having contact pads to which a first conductive structural material is to connect, wherein the substrate may comprise previously deposited material and wherein forming a connection between the contact pads and the first conductive structural material and applying a sacrificial material, comprises:
(a) applying a transition coating to the substrate;
(b) applying the first conductive structural material to the contact pads over the transition locating by application of an electroless plating solution to the contact pads for a sufficient time to form a deposition of desired thickness;
(c) applying a first conductive sacrificial material to the substrate; and
(B) forming a plurality of layers, with the first layer of the plurality of layer being formed on the first conductive structural material and the first conductive sacrificial material such that successive layers are formed adjacent to and adhered to previously formed layers, wherein the formation of at least some of the plurality of layers includes a selective depositing operation which deposits at least one of a second conductive structural material or a second conductive sacrificial material;
wherein at least a plurality of the selective depositing operations comprise:
(1) forming and adhering a selected mask to a previously formed layer;
(2) in presence of a plating solution, conducting an electric current between an anode and the previously formed layer through at least one opening in the mask such that a selected one of the second conductive structural material or the second conductive sacrificial material is deposited onto the previously formed layer to form at least a portion of a layer; and
(3) separating the mask from the previously formed layer; and
(C) separating at least a portion of the first and second conductive sacrificial materials from the first and second conductive structural materials after formation of the plurality of layers.

2. The process of claim 1 wherein after applying the first conductive structural material to the contact pads, the first conductive sacrificial material is applied to the substrate.

3. The process of claim 2 wherein the applied first conductive structural material on the contact pads has a thickness less than a desired thickness and is increased to a desired thickness by electroplating.

4. The process of claim 2 wherein after application of the first conductive sacrificial material to the substrate, the first conductive sacrificial and structural materials are planarized to yield a modified substrate comprising selective regions of the first conductive sacrificial material and the first conductive structural material on to which layers of the second conductive structural material and the second conductive sacrificial material will be deposited.

5. The process of claim 1 wherein the substrate comprises a transition material located on the contact pads.

6. The process of claim 5 wherein the transition material comprises an adhesion promoter.

7. The process of claim 5 wherein the transition material comprises a diffusion barrier.

8. The process of claim 1 wherein the first conductive structural material comprises nickel.

9. The process of claim 1 wherein the first conductive sacrificial material comprises copper.

10. An electrochemical fabrication process for producing a three-dimensional structure form at least one structural material on a semiconductor wafer or portion thereof from a plurality of adhered, the process comprising:
(A) supplying a substrate which comprises a semiconductor wafer, or portion thereof, containing electrical circuitry and having contact pads to which a first conductive structural material is to connect, wherein the substrate may comprise previously deposited material and wherein forming at least a portion of a layer onto the substrate comprises:
(a) shielding at least the contact pads with a shielding material;
(b) depositing a first conductive sacrificial material to unshielded regions using at least one technique selected from the group consisting of (1) direct metallization, (2) direct plating, and (3) electroless deposition;
(c) removing the shielding material after deposition of the first conductive sacrificial material; and
(d) depositing first conductive structural material onto the contact pads; and
(B) forming a plurality of layers, with the first layer of the plurality of layers being formed on the first conductive sacrificial material and on the first conductive structural material, such that successive layers are formed adjacent to and adhered to previously formed layers, wherein the formation of at least some of the plurality of layers includes a selective depositing operation which deposits at least one of a second conductive structural material or a second conductive sacrificial material;
wherein at least a plurality of the selective depositing operations comprise:
(1) forming and adhering a selected mask to a previously formed layer;
(2) in presence of a plating solution, conducting an electric current between an anode and the previously formed layer through at least one opening in the mask such that a selected one of the second conductive sacrificial material or second conductive structural material is deposited onto the previously formed layer to form at least a portion of a layer; and
(3) separating the mask from the previously formed layer; and
separating at least a portion of the first and second sacrificial materials from the first and second structural materials after formation of the plurality of layers.

11. The process of claim 10 wherein after deposition of the first conductive sacrificial material onto the substrate and removal of the shielding material from the contact pads, applying a treatment coating to the contact pads prior to depositing the first conductive structural material.

12. The process of claim 11 wherein the treatment coating comprises a material that enhances effective adhesion between the first conductive structural material and the contact pads.

13. The process of claim 10 wherein the deposition of the first conductive structural material onto the contact pads comprises electroplating the first conductive structural material onto at least one contact pad via electroplating of the first conductive structural material onto the first conductive sacrificial material wherein a region of deposition of the first conductive structural material expands to bridge a dielectric gap separating the first conductive sacrificial material from the at least one contact pad.

14. The process of claim 12 wherein after deposition of the first conductive structural material on the contact pads, the first conductive sacrificial material on the substrate and the first conductive structural material on the contact pads are planarized to yield a modified substrate comprising selective regions of the first conductive sacrificial and the first conductive structural material on to which the plurality of layers comprising the second conductive structural material and the second conductive sacrificial material will be deposited.

15. The process of claim 10 wherein the process further comprises applying a transition material to the contact pads.

16. The process of claim 15 wherein the transition material comprises an adhesion promoter.

17. The process of claim 15 wherein the transition material comprises a diffusion barrier.

18. The process of claim 10 wherein the first conductive structural material comprises nickel.

19. The process of claim 10 wherein the first conductive sacrificial material comprises copper.

20. An electrochemical fabrication process for producing a three-dimensional structure form at least one structural material on a semiconductor wafer, or portion thereof, from a plurality of adhered layers, the process comprising:
(A) supplying a substrate which comprises a semiconductor wafer, or portion thereof, containing electrical circuitry and having contact pads to which a first conductive structural material is to connect and having at least one region of dielectric material where the first conductive structural material is to adhere, wherein the substrate may comprise previously deposited material, and wherein the adhering of the first conductive structural material to the at least one region of dielectric material and applying a first conductive sacrificial material, comprises:
(a) depositing a conductive base material onto the dielectric region,
(b) depositing the first conductive structural material to at least a selected location of the base material, and
(c) if the base material exists in any regions which are not overlaid by the first conductive structural material, subsequently removing any such base material that is not overlaid; and
(d) applying a first conductive sacrificial material to the substrate;
(B) forming a plurality of layers, with the first layer of the plurality of layers being formed on the first conductive sacrificial material and on the first conductive structural material, such that successive layers are formed adjacent to and adhered to previously formed layers, wherein the formation of at least some of the plurality of layers includes a selective depositing operation which deposits at least one of a second conductive structural material or a second conductive sacrificial material;
wherein at least a plurality of the selective depositing operations comprise:
(1) forming and adhering a selected mask to a previously formed layer;
(2) in presence of a plating solution, conducting an electric current between an anode and the previously formed layer through at least one opening in the mask such that a selected one of the second conductive sacrificial material or the second conductive structural material is deposited onto the previously formed layer to form at least a portion of a layer; and
(3) separating the selected mask from the substrate; and
separating at least a portion of the first and second sacrificial materials from the first and second structural materials after formation of the plurality of layers.
